(19) United States
(12) Patent Application Publication
(10) Pub. No.: US 2026/0186221 A1
(43) Pub. Date: Jul. 2, 2026

(54) CHIP PACKAGE INCLUDING INTERCONNECTION LAYERS, METHOD OF FORMING THE SAME, AND METHOD OF TRANSMITTING AND RECEIVING DATA IN CHIP PACKAGE

(71) Applicant: SAMSUNG ELECTRONICS CO., LTD., Suwon-si (KR)

(72) Inventors: Sunghyun NAM, Suwon-si (KR); Joonyong PARK, Suwon-si (KR)

(73) Assignee: SAMSUNG ELECTRONICS CO., LTD., Suwon-si (KR)

(21) Appl. No.: 19/242,229

(22) Filed: Jun. 18, 2025

(30) Foreign Application Priority Data
Dec. 31, 2024 (KR) 10-2024-0202740

(51) Int. Cl. G02B 6/43; G02B 6/42; H01L 21/56; H01L 23/00; H01L 23/31; H01L 23/538; H01L 25/00; H01L 25/18

(52) U.S. Cl. CPC G02B 6/43; G02B 6/4214; G02B 6/4215; H10W 70/611; H10W 70/65; H10W 90/00; H10W 74/01; H10W 74/111; H10W 90/724

(57) ABSTRACT

Provided is a chip package including a chiplet layer including a plurality of chips, an electrical interconnection layer on a first side of the chiplet layer, the electrical interconnection layer including a path configured to transmit electrical signals generated from the chiplet layer, and an optical interconnection layer on a second side of the chiplet layer opposite to the electrical interconnection layer, the optical interconnection layer including a path configured to transmit optical signals generated from the chiplet layer.

### CROSS-REFERENCE TO RELATED APPLICATION

This application claims priority to Korean Patent Application No. 10-2024-0202740,filed on Dec. 31, 2024, in the Korean Intellectual Property Office, the disclosure of which is incorporated by reference herein in its entirety.

### BACKGROUND

### 1. Field

Embodiments of the present disclosure relate to a chip package including a plurality of chips, and more particularly, to a chip package including interconnection layers, a method of forming the chip package, and a method of transmitting and receiving data in the chip package.

### 2. Description of Related Art

According to an optical connection method, optical chips (optical dies), integrating passive and active optical components such as light sources, optical modulators, photodetectors, multiplexers (MUXs), demultiplexers (DEMUXs), optical splitters, and optical waveguides, are arranged on a single package substrate together with electronic chips. This configuration is called “co-packaged optics (COP)”, and optical interconnection structures based on COP are well known.

A role of optical chips is to convert data to be transmitted into optically modulated signals and transmit the signals to chips on other substrates or packages through optical fibers. In addition, another role of optical chips is to convert input optical signals into electrical signals by using an optical detection unit (for example, a photodetector) and a transimpedance amplifier (TIA). In this case, active optical components integrated on optical chips may be electrically connected through wiring to electronic chips on which driving circuits are integrated.

### SUMMARY

One or more embodiments provide a chip package capable of preventing the mixing of electrical signal transmission wiring and optical signal transmission wiring.

One or more embodiments also provide a chip package capable of reducing adverse effects caused by extended electrical signal transmission wiring.

One or more embodiments also provide a chip package that facilitates monitoring of an optical interconnection layer.

One or more embodiments also provide a method of manufacturing a chip package through simplified processes.

One or more embodiments also provide a method of transmitting and receiving data in such a chip package.

Additional aspects will be set forth in part in the description which follows and, in part, will be apparent from the description, or may be learned by practice of embodiments of the disclosure.

According to an aspect of one or more embodiments, there is provided a chip package including a chiplet layer including a plurality of chips, an electrical interconnection layer on a first side of the chiplet layer, the electrical interconnection layer including a path configured to transmit electrical signals generated from the chiplet layer, and an optical interconnection layer on a second side of the chiplet layer opposite to the electrical interconnection layer, the optical interconnection layer including a path configured to transmit optical signals generated from the chiplet layer.

The optical interconnection layer may be between the chiplet layer and a base substrate.

The electrical interconnection layer may be between the chiplet layer and a base substrate.

The optical interconnection layer may include a first transparent layer, and a first optical transmission layer on the first transparent layer, the first optical transmission layer being configured to operate as a waveguide;

The chip package may further include a second transparent layer on the first optical transmission layer, and a second optical transmission layer on the second transparent layer.

The chip package may further include a mirror on the first optical transmission layer.

The first optical transmission layer may include a plurality of optical elements, and the chip package may further include a protective layer on the first optical transmission layer and the plurality of optical elements.

The plurality of chips may include a light-emitting chip including a light source, and a light-receiving chip including a photodetector element, wherein the first optical transmission layer may include a first optical element configured to change a propagation direction of light incident from the light-emitting chip, and a second optical element configured to change a propagation direction of light incident through the first optical element to direct the light onto the light-receiving chip.

The first optical transmission layer may further include an optical multiplexer and an optical demultiplexer that are between the first optical element and the second optical element.

The first optical element and the second optical element may include a grating coupler.

The light source may include a vertical-cavity surface-emitting laser (VCSEL), and the VCSEL may include a metasurface at a light-emitting surface of the VCSEL, the metasurface being configured to deflect emitted light toward the first optical element.

The plurality of chips may be on the electrical interconnection layer, and the chiplet layer further may include a molding layer filling space between the plurality of chips and enclosing the plurality of chips.

The chip package may further include a chip on the electrical interconnection layer and exposing the molding layer.

The chip exposed by the molding layer may include a chip stack including a plurality of chips stacked in a vertical direction.

The chip stack may include high bandwidth memory (HBM).

According to another aspect of one or more embodiments, there is provided a method of manufacturing a chip package, the method including forming an electrical interconnection layer on a base substrate, forming a chiplet layer on the electrical interconnection layer, the chiplet layer including a plurality of chips, and forming an optical interconnection layer on the chiplet layer opposite to the electrical interconnection layer.

The forming of the chiplet layer may include forming connection elements spaced apart from each other on the electrical interconnection layer, forming the plurality of chips to contact the connection elements, and forming a molding layer and planarizing a surface of the molding layer, the molding layer filling space between the plurality of chips and enclosing the plurality of chips.

The forming of the optical interconnection layer may include forming a first transparent layer on the chiplet layer, and forming a first optical transmission layer on the first transparent layer.

The method may further include forming a second transparent layer on the first optical transmission layer, and forming a second optical transmission layer on the second transparent layer.

According to still another aspect of one or more embodiments, there is provided a method of transmitting and receiving data in a chip package, the method including transmitting a first electrical signal generated from a first chip to a second chip adjacent to the first chip, and outputting an optical signal corresponding to the first electrical signal from the second chip and transmitting the optical signal to a third chip, wherein the first electrical signal is transmitted on a first side of the first chip and a first side of the second chip, and the optical signal is transmitted on a second side of the second chip and a second side of the third chip opposite to the first side.

### BRIEF DESCRIPTION OF DRAWINGS

The above and other aspects, features, and advantages of embodiments of the disclosure will be more apparent from the following description taken in conjunction with the accompanying drawings, in which:

FIGS. 1, 2, 3, 4, 5, 6, 7, 8, 9, and 10 are cross-sectional views illustrating first, second, third, fourth, fifth, sixth, seventh, eighth, ninth, and tenth chip packages including interconnection layers, according to one or more embodiments;

FIG. 11 is a plan view illustrating an example of a two-dimensional light source array included in a light-emitting chip in the first to tenth chip packages;

FIG. 12 is a cross-sectional view illustrating, as an example, a light source included in the light source array shown in FIG. 11;

FIG. 13 is a cross-sectional view illustrating an example in which a metasurface is provided on an upper surface of a substrate in the light source shown in FIG. 12.

FIG. 14 is a cross-sectional view illustrating an example in which an optical multiplexer and an optical demultiplexer are provided between a first optical element and a second optical element in an optical transmission layer of the first to tenth chip packages;

FIG. 15 is a plan view illustrating an example of a planar configuration of the optical transmission layer shown in FIG. 14;

FIGS. 16, 17, 18, 19, 20, 21, 22, 23, 24, 25, 26, 27, 28, 29, 30, 31, and 32 are cross-sectional views sequentially illustrating operations in a method of manufacturing a chip package, according to one or more embodiments; and

FIG. 33 is a block diagram illustrating data transmission and reception in a chip package according to one or more embodiments.

### DETAILED DESCRIPTION

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, chip packages including interconnection layers, methods of forming the chip packages, and methods of transmitting and receiving data in the chip packages will be described according to one or more embodiments with reference to the accompanying drawings. In the drawings, the thicknesses of layers or regions may be exaggerated for clarity of illustration.

The one or more embodiments described herein are for illustrative purposes only, and various modifications may be made therein. In addition, it will also be understood that when a layer is referred to as being “above” or “on” another layer or substrate, it may be directly on the other layer or substrate or be above the layer or substrate without making contact with the layer or substrate. In the drawings, like reference numerals refer to the like elements.

As used herein, singular forms may include plural forms as well unless the context clearly indicates otherwise. It will be further understood that the terms “comprises” and/or “comprising” used herein specify the presence of stated features or elements, but do not preclude the presence or addition of one or more other features or elements.

An element referred to with the definite article or a demonstrative determiner may be construed as the element or the elements even though it has a singular form. Operations of a method may be performed in an appropriate order unless explicitly described in terms of order or described to the contrary. Operations of a method are not limited to the stated order thereof.

In the disclosure, terms such as “unit” or “module” may be used to denote a unit that has at least one function or operation and is implemented with hardware, software, or a combination of hardware and software.

Furthermore, line connections or connection members between elements depicted in the drawings represent functional connections and/or physical or circuit connections by way of example, and in actual applications, they may be replaced or embodied with various additional functional connections, physical connections, or circuit connections.

In addition, examples or terms are used for the purpose of description and are not intended to limit the scope of the disclosure unless defined by the claims.

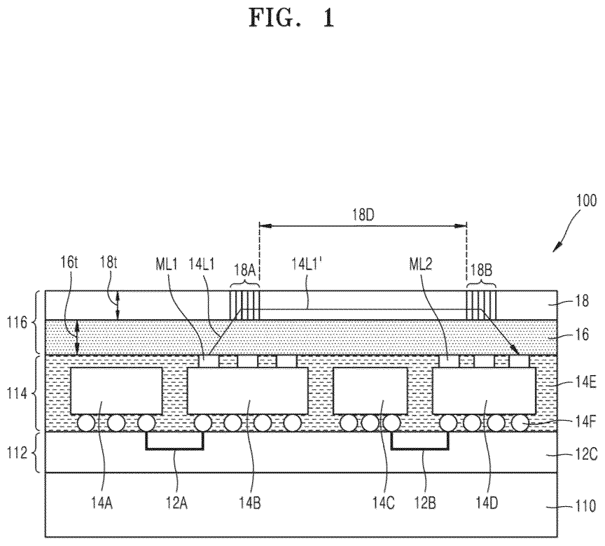

FIG. 1 illustrates a first chip package 100 including interconnection layers according to one or more embodiments.

Referring to FIG. 1, the first chip package 100 includes an electrical interconnection layer 112, a chiplet layer 114, and an optical interconnection layer 116. The electrical interconnection layer 112 is provided for transmitting and receiving electrical signals or data between a plurality of chips including a first chip 14A, a second chip 14B, a third chip 14C, and a fourth chip 14D included in the chiplet layer 114. The electrical interconnection layer 112 may include a plurality of conductive wires including a first wire 12A and a second wire 12B, and an insulating layer 12C. The first and second wires 12A and 12B may connect some or all of the first to fourth chips 14A, 14B, 14C, and 14D to each other. The first and second wires 12A and 12B may be embedded in the insulating layer 12C, and only portions of the first and second wires 12A and 12B that are in contact with connection elements 14F may be exposed. The electrical interconnection layer 112 may be referred to as an electricity interconnection or an electricity interconnection layer. The optical interconnection layer 116 is provided for transmitting and receiving optical signals or data between the first to fourth chips 14A to 14D included in the chiplet layer 114. The optical interconnection layer 116 may include an optical transmission layer 18 provided for transmitting optical signals or optical data. Considering the role of the optical interconnection layer 116, the optical interconnection layer 116 may also be referred to as an optical interposer layer. The optical transmission layer 18 may also be referred to as an optical transport layer, a waveguide, or a waveguide layer. The electrical interconnection layer 112, the chiplet layer 114, and the optical interconnection layer 116 may be sequentially stacked on a base substrate 110 in the stated order. The electrical interconnection layer 112 may be directly provided on the base substrate 110 and may be in direct contact with the base substrate 110. However, the electrical interconnection layer 112 is not limited thereto. In one example, an additional material layer may be further provided between the base substrate 110 and the electrical interconnection layer 112. The additional material layer may be included in the base substrate 110 or the electrical interconnection layer 112. In one example, the base substrate 110 may be a single-layer or two-layer substrate, but is not limited thereto. In one example, the base substrate 110 may include a packaging substrate or a printed circuit board (PCB), but is not limited thereto. In one example, the first and second wires 12A and 12B included in the electrical interconnection layer 112 may be formed on the base substrate 110. Therefore, in the example, both the base substrate 110 and the electrical interconnection layer 112 may collectively be referred to as a base substrate. The electrical interconnection layer 112 may include the first wire 12A connecting the first chip 14A and the second chip 14B to each other, and the second wire 12B connecting the third chip 14C and the fourth chip 14D to each other. For example, in the electrical interconnection layer 112, the first chip 14A and the second chip 14B may be connected to each other by one or more wires including the first wire 12A, and the third chip 14C and the fourth chip 14D may be connected to each other by one or more wires including the second wire 12B. In one example, electrical signals for operations of the second chip 14B or control signals for controlling operations of the second chip 14B may be transmitted through the first wire 12A. In one example, the electrical signals for operations of the second chip 14B may include driving signals for a light-emitting device, and the control signals may include data signals. According to the control signals, light emitted from the light-emitting device may be modulated, and the modulation may be controlled. To this end, the control signals may include optical modulation signals or optical modulation control signals. In one example, electrical signals may be transmitted from the fourth chip 14D to the third chip 14C through the second wire 12B. The electrical signals may include data signals included in the control signals that are transmitted as optical signals and then optoelectronically converted by the fourth chip 14D.

The optical interconnection layer 116 is disposed on the chiplet layer 114 opposite to the electrical interconnection layer 112 in a vertical direction (stacking direction) perpendicular to an upper surface of the electrical interconnection layer 112. The optical interconnection layer 116 may include a transparent substrate 16 and the optical transmission layer 18 that are sequentially stacked. The transparent substrate 16 is provided on an upper surface of the chiplet layer 114. The transparent substrate 16 may entirely be provided on and cover the upper surface of the chiplet layer 114 and may be in direct contact with the upper surface of the chiplet layer 114. The transparent substrate 16 may also be referred to as a first transparent layer.

In one example, the transparent substrate 16 may be or include a material layer transparent to visible light and infrared light. In one example, the transparent substrate 16 may include a material layer transparent to light used in optical communication. In one example, the transparent substrate 16 may include a material layer transparent to visible light (for example, red light) adjacent to infrared light, but this is not limited thereto. In one example, the transparent substrate 16 may include a material layer transparent to visible light having a shorter wavelength than red light. In one example, the transparent substrate 16 may include a glass substrate, but is not limited thereto. For example, in the transparent substrate 16, a portion corresponding to the chiplet layer 114 may have a thickness 16t in the vertical direction. The thickness 16t may be constant and may be within a range of several micrometers (μm) to several hundred micrometers (μm). In one example, the minimum of the thickness 16t may be about 1 μm to about 9 μm, and the maximum of the thickness 16t may be about 100 μm to about 900 μm. For example, the thickness 16t may have any value between the minimum and the maximum. The optical transmission layer 18 may be provided on an upper surface of the transparent substrate 16. The optical transmission layer 18 may entirely be provided on and cover the upper surface of the transparent substrate 16 and may be in direct contact with the upper surface of the transparent substrate 16. In one example, the optical transmission layer 18 may transmit light 14L1, emitted from a portion of the chiplet layer 114 and passing through the transparent substrate 16, to another portion of the chiplet layer 114. The light 14L1 may include an optical signal or optical data. In one example, the optical transmission layer 18 may include a first optical element 18A and a second optical element 18B that are for changing the propagation path of light. In addition, the optical transmission layer 18 may include other optical elements or optical devices. The first optical element 18A and the second optical element 18B are spaced apart from each other in a horizontal direction parallel to an upper surface of the optical transmission layer 18. In one example, a separation distance 18D between the first optical element 18A and the second optical element 18B may be several centimeters (cm). For example, the separation distance 18D in the horizontal direction may range from about 1 cm to less than about 10 cm, from about 2 cm to about 9 cm, from about 3 cm to about 8 cm, or from about 4 cm to about 7 cm. However, one or more embodiments are not limited thereto. For example, in the optical transmission layer 18, a portion corresponding to the chiplet layer 114 may have a thickness 18t in the vertical direction. The thickness 18t may be constant, but is not limited thereto. The thickness 18t of the optical transmission layer 18 may range from several hundred nanometers (nm) to several micrometers (μm). In one example, the minimum of the thickness 18t may be about 100 nm to about 900 nm, and the maximum of the thickness 18t may be about 1 μm to about 9 μm. For example, the thickness 18t may have any value between the minimum and the maximum. In one example, the first optical element 18A may correspond to the second chip 14B of the chiplet layer 114. In one example, the first optical element 18A may be provided above the second chip 14B. The first optical element 18A may change the propagation path of light 14L1 incoming from the second chip 14B such that the light 14L1 may propagate inside the optical transmission layer 18 along the optical transmission layer 18. The propagation direction of light 14L1′ of which the optical path is changed by the first optical element 18A may be parallel to the upper surface of the transparent substrate 16. In one example, the first optical element 18A may be one type of optical coupler (e.g., an input optical coupler). For example, the first optical element 18A may include a grating coupler, but is not limited thereto. The second optical element 18B may correspond to the fourth chip 14D of the chiplet layer 114. In one example, the second optical element 18B may be provided above the fourth chip 14D. The second optical element 18B may change the propagation direction of the light 14L1′, which is incident on the second optical element 18B after the optical path of the light 14L1′ is changed by the first optical element 18A, such that the light 14L1′ may propagate toward the fourth chip 14D. In one example, the second optical element 18B may be one type of optical coupler (e.g., an output optical coupler). In one example, the second optical element 18B may include a grating coupler, but is not limited thereto. In one example, the first and second optical elements 18A and 18B may be formed using meta-technology. In one example, the first and second optical elements 18A and 18B may include metasurfaces including a plurality of meta-patterns. The arrangement and shapes of the meta-patterns may be configured considering the incidence angle of incoming light and the propagation direction of outgoing light.

In one example, the optical transmission layer 18 may be or include a material layer that is transparent to visible light and/or infrared light and has a relatively low absorption rate for visible light and/or infrared light. In one example, the optical transmission layer 18 may include a material layer that is transparent to light used for optical communication and has a relatively low absorption rate for light used for optical communication. In one example, the optical transmission layer 18 may include a material layer that is transparent to visible light (for example, red light) adjacent to infrared light in the visible light band and has a relatively low absorption rate for the visible light (for example, red light). However, the optical transmission layer 18 is not limited thereto. In one example, the optical transmission layer 18 may include a material layer that is transparent to visible light having a wavelength that is shorter than red light and has a relatively low absorption rate for the visible light having a wavelength shorter than red light. In one example, the optical transmission layer 18 and the transparent substrate 16 may have the same material or different materials. In one example, the optical transmission layer 18 may include a silicon nitride (SiN) layer, a silicon oxide (for example, SiO₂) layer, a titanium oxide (for example, TiO₂) layer, or a silicon (Si) layer, but is not limited thereto.

The chiplet layer 114, which is disposed between the electrical interconnection layer 112 and the optical interconnection layer 116 in the vertical direction, may include the first to fourth chips 14A to 14D, a molding layer 14E, and the connection elements 14F. The first to fourth chips 14A to 14D may be spaced apart from each other in the horizontal direction. The first to fourth chips 14A to 14D may be electrically connected (bonded) to the electrical interconnection layer 112 via the connection elements 14F. The molding layer 14E may be a material layer that fills space between the first to fourth chips 14A to 14D and encloses all of the first to fourth chips 14A to 14D. The molding layer 14E entirely be provided on and cover exposed surfaces of the first to fourth chips 14A to 14D. For example, the molding layer 14E may cover all portions of the first to fourth chips 14A to 14D except for portions that are in contact with the electrical interconnection layer 112 and portions to be in contact with the optical interconnection layer 116. The connection elements 14F may also be covered by the molding layer 14E except for portions that are in contact with the electrical interconnection layer 112 and the first to fourth chips 14A to 14D. In one example, the molding layer 14E may include an optical polymer layer or an optical resin layer, but is not limited thereto. In one example, the optical polymer layer may include polymethyl methacrylate (PMMA), polycarbonate, or polystyrene, but is not limited thereto. The molding layer 14E, in which the first to fourth chips 14A to 14D are embedded as described above, may have a flat upper surface. The optical interconnection layer 116 may be provided on the flat upper surface of the molding layer 14E.

The chiplet layer 114 is illustrated as including four chips. However, the chiplet layer 114 may include more than four or fewer than four chips.

In one example, the first chip 14A may include a chip having an integrated circuit. In one example, the first chip 14A may include an electronic chip or a semiconductor chip (for example, a memory chip or a system semiconductor chip). The first chip 14A may be connected to the electrical interconnection layer 112. In one example, the first chip 14A may be connected to the first wire 12A of the electrical interconnection layer 112 via the connection elements 14F that are conductive. The connection elements 14F may be provided between the first chip 14A and the electrical interconnection layer 112, and the electrical interconnection layer 112 may include a plurality of wires that are spaced apart from each other and are connected to the connection elements 14F. In one example, the connection elements 14F may include solder balls. The second chip 14B may be or include a chip used as a light source. The second chip 14B may include a light source array. In one example, the light source array may include a one-dimensional array or a two-dimensional array. In one example, light sources of the light source array may include a laser light source such as vertical-cavity surface-emitting laser (VCSEL). However, one or more embodiments are not limited thereto. In one example, the VCSEL may perform a modulation in response to data (an electrical signal) received from the first chip 14A through the first wire 12A to output light for transmitting the data. A driving signal for the VCSEL may also be provided from the first chip 14A to the second chip 14B through the first wire 12A. A plurality of different pieces of data may be transmitted from the first chip 14A to the second chip 14B, and the different pieces of data may be converted into optical signals by the light source array included in the second chip 14B. Then, the optical signals may be transmitted. The different pieces of data converted into the optical signals (optical data) may be delivered to the optical interconnection layer 116. Then, the optical signals or data may be multiplexed and transmitted or may be transmitted through individual channels.

For example, the second chip 14B may operate as a light source for emitting light necessary for optical data transmission and may also perform an optical modulation operation. Light emitted from the second chip 14B may fall within a range from the visible light band to the infrared band. In one example, the light source included in the second chip 14B may emit light having a wavelength of about 500 nm to about 1600 nm, about 600 nm to about 1600 nm, about 700 nm to about 1600 nm, about 800 nm to about 1600 nm, about 800 nm to about 1550 nm, about 800 nm to about 1350 nm, or about 800 nm to about 1300 nm. However, the wavelength range of light emitted by the light source included in the second chip 14B is not limited thereto.

Light emitted from the second chip 14B may be incident on the optical interconnection layer 116 after passing through a microlens ML1 provided on a light-emitting surface of the second chip 14B. The microlens ML1 may be disposed between the second chip 14B and the optical interconnection layer 116. Although the microlens ML1 is illustrated as being included in the chiplet layer 114, the microlens ML1 may be included in the optical interconnection layer 116. In one example, any optical element capable of delivering light emitted from the second chip 14B to a designated location (for example, the first optical element 18A) in the optical interconnection layer 116 may replace the microlens ML1. In one example, a meta-lens formed using meta-technology may be provided at the same position instead of the microlens ML1. A number of microlenses ML1 equal to the number of light sources in the light source array of the second chip 14B may be arranged to correspond one-to-one to the light sources.

The second chip 14B may be connected to the first wire 12A of the electrical interconnection layer 112 via the connection elements 14F.

In one example, the third chip 14C may include a chip having an integrated circuit. In one example, the third chip 14C may include a semiconductor chip (for example, a memory chip or a system semiconductor chip) or an electronic chip. The third chip 14C may be the same as or different from the first chip 14A in terms of structure and/or operation. In one example, the third chip 14C may be configured to process or store data transmitted via the fourth chip 14D, but is not limited thereto. The third chip 14C may be mounted between the second chip 14B and the fourth chip 14D. The third chip 14C may be connected to the second wire 12B of the electrical interconnection layer 112 via the connection elements 14F. Electrical signals (data) may be transmitted and received between the third chip 14C and the fourth chip 14D through the second wire 12B, and the electrical signals may be signals that have undergone optoelectronic conversion in the fourth chip 14D before being transmitted. A plurality of wires, such as the second wire 12B, may be provided between the third chip 14C and the fourth chip 14D.

The fourth chip 14D may be or include a chip that receives optical signals (optical data) incident from the optical interconnection layer 116 and performs optoelectronic conversion. The fourth chip 14D may include a light-receiving element. In one example, the fourth chip 14D may include a plurality of light-receiving elements. The light-receiving elements may be provided as a one-dimensional or two-dimensional array. In one example, the light-receiving elements may be arranged to correspond to the light source array included in the second chip 14B. In one example, the number of light-receiving elements may be the same as or different from the number of light sources in the light source array of the second chip 14B. However, one or more embodiments are not limited thereto. In one example, the light-receiving elements may include photodiodes (PDs), but are not limited thereto. The fourth chip 14D may receive light incident from the second optical element 18B of the optical interconnection layer 116 and may optoelectronically convert the light into an electrical signal (data). The electrical signal may be transmitted to the third chip 14C via the second wire 12B. Light may be incident on the fourth chip 14D from the second optical element 18B through a second microlens ML2. The second microlens ML2 may increase the light reception efficiency of the fourth chip 14D for light incident from the second optical element 18B. The second microlens ML2 may be provided between the optical interconnection layer 116 and the fourth chip 14D. The second microlens ML2 may be included in the chiplet layer 114. As another example, the second microlens ML2 may be included in the optical interconnection layer 116. In one example, second microlenses ML2 corresponding one-to-one to the light-receiving elements of the fourth chip 14D may be provided. In one example, the number of second microlenses ML2 may be the same as the number of light-receiving elements of the fourth chip 14D. In one example, any components capable of performing the same operation as the second microlenses ML2 may be used instead of the second microlenses ML2. In one example, meta-lenses formed using meta-technology may be used instead of the second microlenses ML2. The fourth chip 14D may be connected to the second wire 12B of the electrical interconnection layer 112 via the connection elements 14F. The connection elements 14F may be bonding elements that bond the chiplet layer 114 and the electrical interconnection layer 112 to each other.

Each of the first to fourth chips 14A to 14D of the chiplet layer 114 may also be referred to as a die.

Looking at the flow of electrical signals and optical signals during operations of the first chip package 100, the electrical signals are transmitted and received through a first side of the chiplet layer 114, and the optical signals are transmitted and received through a second side of the chiplet layer 114. The second side may be the opposite the first side. In one example, the electrical signals are transmitted and received at a lower side of the chiplet layer 114 through the electrical interconnection layer 112, and the optical signals are transmitted and received at an upper side of the chiplet layer 114 through the optical interconnection layer 116.

As described above, the transmission-reception paths for electrical signals are completely separated from the transmission-reception path of optical signals, the transmission-reception paths for electrical signals are formed between adjacent chips, and the transmission-reception path of optical signals is formed between relatively distant chips. As a result, the length of wiring for transmitting and receiving electrical signals may be reduced. Therefore, parasitic effects, which may occur when wiring for transmitting and receiving electrical signals are long, may be prevented, optical transmission efficiency may be improved, and data transmission and reception time may be reduced. Therefore, the first chip package 100 or a computing system including the first chip package 100 may have a relatively high operating speed and low power consumption and may be manufactured through simple processes.

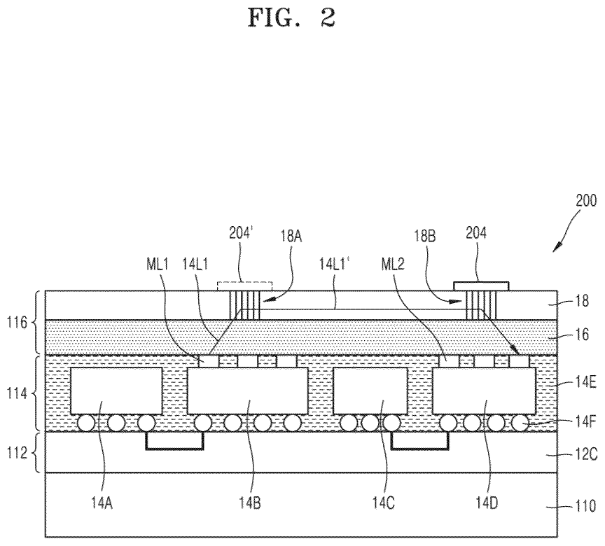

FIG. 2 illustrates a second chip package 200 according to one or more embodiments. The second chip package 200 may be a modification of the first chip package 100. Therefore, the description of the second chip package 200 will cover parts that differ from the first chip package 100, and elements identical to those in FIG. 1 are denoted with the same reference numerals and are not repeatedly described. This applies to all chip packages described hereinafter.

Referring to FIG. 2, the second chip package 200 may include a light reflection mirror 204 corresponding to a second optical element 18B of an optical interconnection layer 116. The light reflection mirror 204 may be disposed on the second optical element 18B and may entirely be provided on and cover the second optical element 18B. A reflective surface of the light reflection mirror 204 may face the second optical element 18B. The light reflection mirror 204 may be in direct contact with the second optical element 18B or may not be in contact with and spaced apart from the second optical element 18B. In one example, the light reflection mirror 204 may be disposed on the second optical element 18B with a gap between the light reflection mirror 204 and the second optical element 18B. The light reflection mirror 204 is provided such that when light is incident on the second optical element 18B, a portion of the incident light propagating upward from the second optical element 18B may be reflected downward by the light reflection mirror 204. As a result, the amount of light incident on the fourth chip 14D, which is disposed below the second optical element 18B, may be greater than when the light reflection mirror 204 is not present. Thus, the light reflection mirror 204 may be considered an optical element that enhances light reception efficiency or light collection efficiency. The light reflection mirror 204 may be parallel to the upper surface of an optical transmission layer 18.

In one example, a light reflection mirror 204′ may also be provided on a first optical element 18A. The light reflection mirror 204′ may be a light reflection element designed to reflect downward a portion of light that is incident on the first optical element 18A and output upward from the first optical element 18A. The light reflection mirror 204′ may be parallel to the upper surface of the optical transmission layer 18, or may be inclined with respect to the upper surface of the optical transmission layer 18. In this case, the light reflection mirror 204′ may be inclined at an acute angle with respect to the upper surface of the optical transmission layer 18. Due to the light reflection mirror 204′ provided on the first optical element 18A, the amount of light transmitted from the first optical element 18A to the second optical element 18B may be greater than when the light reflection mirror 204′ is not present.

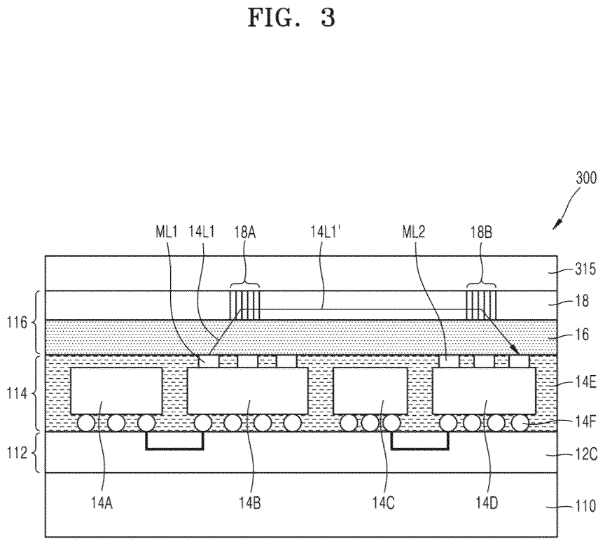

FIG. 3 illustrates a third chip package 300 according to one or more embodiments. The third chip package 300 may be one of modifications of the first chip package 100.

Referring to FIG. 3, the third chip package 300 may further include a protective layer 315 (passivation layer) to protect optical devices and/or optical elements on an optical interconnection layer 116. The protective layer 315 may be provided on an optical transmission layer 18 and may partially or entirely be provided on and cover an upper surface of the optical transmission layer 18. In one example, the protective layer 315 may be provided on and cover at least first and second optical elements 18A and 18B of the optical transmission layer 18. The protective layer 315 may have a uniform thickness as a whole. In one example, the protective layer 315 may be or include a silicon oxide layer (for example, a SiO₂ layer). In one example, the third chip package 300 may also include light reflection mirrors 204 and 204′ (refer to FIG. 2) like the second chip package 200. In one example, the protective layer 315 and the optical interconnection layer 116 may be collectively referred to as an optical interconnection layer.

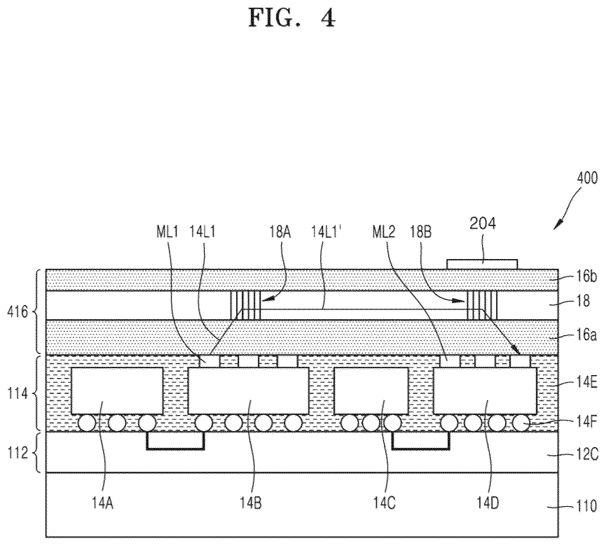

FIG. 4 illustrates a fourth chip package 400 according to one or more embodiments. The fourth chip package 400 may also be one of modifications of the first chip package 100.

Referring to FIG. 4, an optical interconnection layer 416 of the fourth chip package 400 may correspond to a layer structure in which the optical transmission layer 18 of the first chip package 100 is embedded within the transparent substrate 16. In one example, the optical interconnection layer 416 may include a layered structure in which a lower transparent layer 16a, an optical transmission layer 18, and an upper transparent layer 16b are sequentially stacked in the vertical direction. The lower transparent layer 16a and the upper transparent layer 16b may include the same material as a material included in the transparent substrate 16 of the first chip package 100. A light reflection mirror 204 may be provided on the upper transparent layer 16b. The light reflection mirror 204 may be provided on and cover a second optical element 18B. In one example, the light reflection mirror 204 may be provided between the optical transmission layer 18 and the upper transparent layer 16b. The light reflection mirror 204′ of the second chip package 200 may also be included in the fourth chip package 400. In this case, the light reflection mirror 204′ may be provided on the upper transparent layer 16b or between the upper transparent layer 16b and a first optical element 18A.

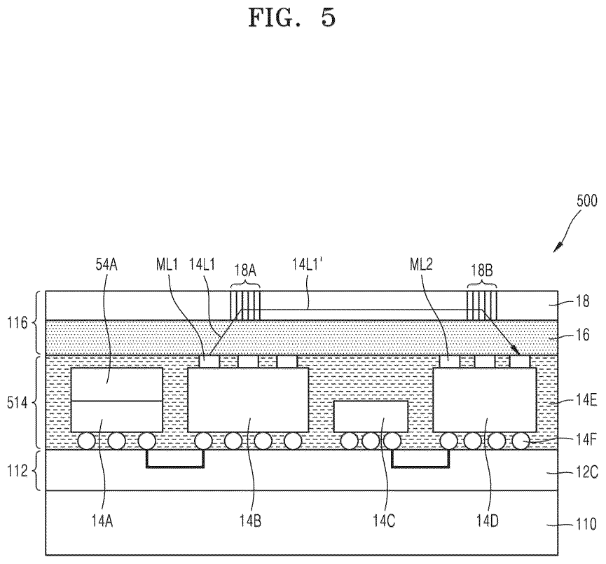

FIG. 5 illustrates a fifth chip package 500 according to one or more embodiments. The fifth chip package 500 may also be one of modifications of the first chip package 100.

Referring to FIG. 5, a chiplet layer 514 of the fifth chip package 500 may further include a fifth chip 54A provided on a first chip 14A in addition to first to fourth chips 14A to 14D. The first chip 14A and the fifth chip 54A may be vertically stacked. In one example, the first chip 14A and the fifth chip 54A may be substantially identical in structure or operation or may be different from each other. In one example, the first chip 14A and the fifth chip 54A may include memory chips. Two or more chips may be vertically stacked on the first chip 14A within a range in which planarization of the molding layer 14E is possible.

At least one of the aspects of the second to fourth chip packages 200, 300, and 400 described above may be applied to the fifth chip package 500. For example, in the fifth chip package 500, an optical transmission layer 18 may be embedded in a transparent substrate 16.

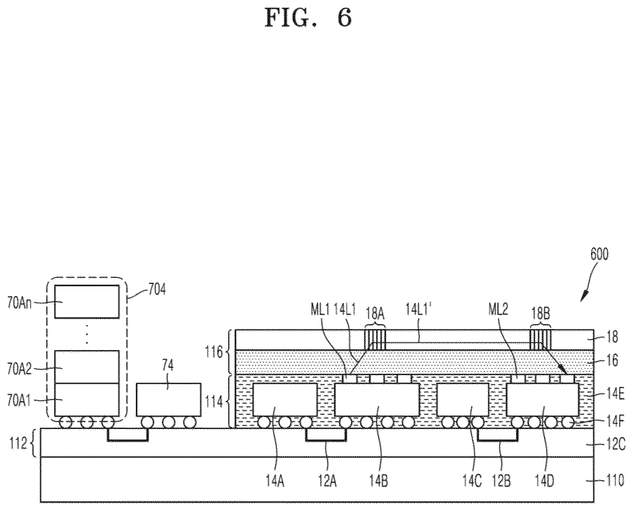

FIG. 6 illustrates a sixth chip package 600 according to one or more embodiments. The sixth chip package 600 may also be one of modifications of the first chip package 100.

Referring to FIG. 6, in the sixth chip package 600, some of chips formed on an electrical interconnection layer 112 are connected to each other through the electrical interconnection layer 112 and an optical interconnection layer 116, and the remaining chips are connected to each other through only the electrical interconnection layer 112. For example, in addition to first to fourth chips 14A to 14D, a sixth chip 74 and a first chip stack 704 may also be provided on the electrical interconnection layer 112. In one example, the sixth chip 74 may include a semiconductor chip or an electronic chip. In one example, the first chip stack 704 may include a plurality of chips 70A1, 70A2, . . . , and 70An stacked in the vertical direction, where n=1, 2, 3, . . . . The chips 70A1, 70A2, . . . , and 70An may have the same structure and operation. In one example, each of the chips 70A1, 70A2, . . . , and 70An may include a memory chip (for example, dynamic random access memory (DRAM)), and the first chip stack 704 may include high bandwidth memory (HBM). A significant height difference may exist between the first chip stack 704 and the first to fourth chips 14A to 14D and the sixth chip 74 that are provided around the first chip stack 704. Therefore, when the first chip stack 704 and the first to fourth chips 14A to 14D are molded together, it may be difficult to planarize a molding layer 14E. Therefore, the first chip stack 704 may be excluded from a molding process. In addition, the sixth chip 74 may be mounted closer to the first chip stack 704 than to the first chip 14A. In one example, the sixth chip 74 may include a semiconductor chip related to operations of the first chip stack 704. The distance between the sixth chip 74 and the first chip 14A may be greater than the distance between the first chip 14A and the second chip 14B. For example, because the sixth chip 74 is not directly adjacent to the first chip 14A, the sixth chip 74 may be excluded from the molding process of the first to fourth chips 14A to 14D. As a result, among the first to fourth chips 14A to 14D, the sixth chip 74, and the first chip stack 704 that are mounted on the electrical interconnection layer 112, only the first to fourth chips 14A to 14D that are arranged adjacent to each other may be molded by the molding layer 14E, and the sixth chip 74 and the first chip stack 704 may be excluded from the molding process. An optical interconnection layer 116 may be provided on the molding layer 14E.

As a result, in the sixth chip package 600, a data transmission-reception path for some chips may be formed in the same manner as in the first chip package 100, and a data transmission-reception path for the remaining chips may be formed only through the electrical interconnection layer 112. As described above, data transmission-reception paths may be selected according to the arrangement of chips mounted on a base substrate 110 and the configuration of each chip to optimize data transmission and reception and increase data transmission-reception efficiency.

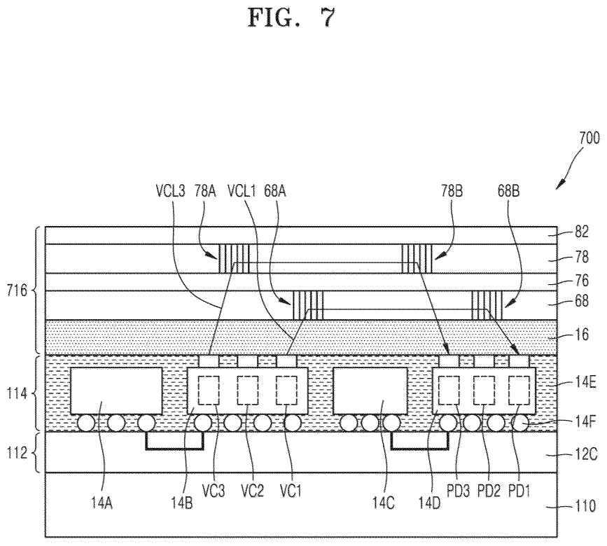

FIG. 7 illustrates a seventh chip package 700 according to one or more embodiments. The seventh chip package 700 may also be one of modifications of the first chip package 100.

Referring to FIG. 7, an optical interconnection layer 716 may include a plurality of optical transmission layers 68 and 78 and a plurality of protective layers 76 and 82 that are provided on a transparent substrate 16. In one example, the optical interconnection layer 716 may include a first optical transmission layer 68, a first protective layer 76, a second optical transmission layer 78, and a second protective layer 82 that are sequentially stacked on the transparent substrate 16 in the vertical direction perpendicular to an upper surface of the transparent substrate 16. In one example, additional optical transmission layers and protective layers may be alternately stacked on the second protective layer 82, such as a third optical transmission layer, a third protective layer, a fourth optical transmission layer, a fourth protective layer, and on the like. The number of alternating layers may be limited considering the number of light sources included in a second chip 14B. The first and second optical transmission layers 68 and 78 may include the same material or different materials. In one example, the first and second optical transmission layers 68 and 78 may include the same material as a material included in the optical transmission layer 18 described with reference to FIG. 1. The first and second protective layers 76 and 82 may include a material that is transparent to light emitted from the second chip 14B with a relatively low light absorption rate. In one example, the first and second protective layers 76 and 82 may include the same material or different materials. In one example, the first and second protective layers 76 and 82 may include silicon oxide (SiO₂), but are not limited thereto. The first optical transmission layer 68 may include a third optical element 68A and a fourth optical element 68B that are spaced apart from each other. The third optical element 68A may have the same structure and perform the same role (operation) as the first optical element 18A described with reference to FIG. 1. The fourth optical element 68B may have the same structure and perform the same role (operation) as the second optical element 18B described with reference to FIG. 1. The third optical element 68A may correspond to a first light source VC1 included in a second chip 14B, and the fourth optical element 68B may correspond to a first light-receiving element PD1 included in a fourth chip 14D. Therefore, light VCL1 emitted from the first light source VC1 of the second chip 14B may be received by the first light-receiving element PD1 of the fourth chip 14D after passing through the third optical element 68A and the fourth optical element 68B. The second optical transmission layer 78 may include a fifth optical element 78A and a sixth optical element 78B that are apart from each other. The fifth and sixth optical elements 78A and 78B may not overlap the third and fourth optical elements 68A and 68B in the vertical direction. The fifth optical element 78A may have the same structure and perform the same role (operation) as the first optical element 18A described with reference to FIG. 1. The sixth optical element 78B may have the same structure and perform the same role (operation) as the second optical element 18B described with reference to FIG. 1. The fifth and sixth optical elements 78A and 78B may be formed by patterning portions of the second optical transmission layer 78, and may thus include the same material as the second optical transmission layer 78. The fifth optical element 78A may correspond to a third light source VC3 of the second chip 14B, and the sixth optical element 78B may correspond to a third light-receiving element PD3 of the fourth chip 14D. Therefore, light VCL3 emitted from the third light source VC3 of the second chip 14B may be received by the third light-receiving element PD3 of the fourth chip 14D after passing through the fifth optical element 78A and the sixth optical element 78B.

First to third light sources VC1 to VC3 are examples of some light sources of the second chip 14B. First to third light-receiving elements PD1 to PD3 are examples of some light-receiving elements of the fourth chip 14D.

In one example, a third optical transmission layer may be provided on the second protective layer 82 to transmit light emitted from the second light source VC2 of the second chip 14B to the second light-receiving element PD2 of the fourth chip 14D. The third optical transmission layer may include a seventh optical element corresponding to the second light source VC2 and an eighth optical element (corresponding to the second light-receiving element PD2. Therefore, light emitted from the second light source VC2 of the second chip 14B may be received by the second light-receiving element PD2 of the fourth chip 14D after passing through the seventh and eighth optical elements. In one example, the third optical transmission layer may be provided between the first protective layer 76 and the second optical transmission layer 78. In this case, a protective layer may be provided between the third optical transmission layer and the second optical transmission layer 78.

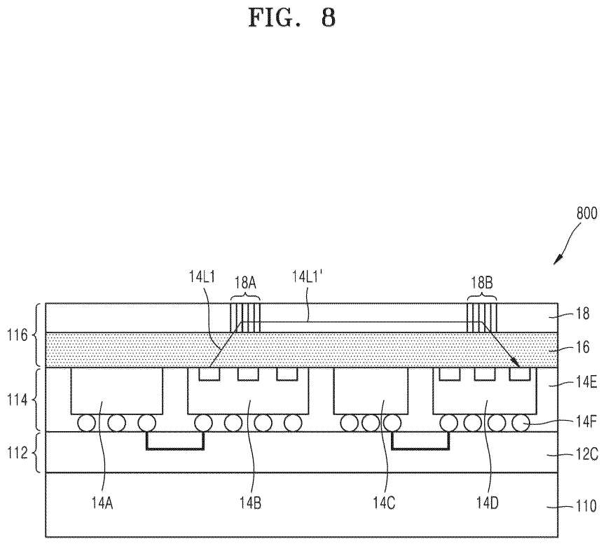

FIG. 8 illustrates an eighth chip package 800 according to one or more embodiments. The eighth chip package 800 may also be one of modifications of the first chip package 100.

Referring to FIG. 8, the eighth chip package 800 corresponds to a modification of the first chip package 100 in which the first microlens ML1 is provided in the second chip 14B, and the second microlens ML2 is provided in the fourth chip 14D. In the eighth chip package 800, a molding layer 14E may be provided on and cover all surfaces of first to fourth chips 14A to 14D except for upper surfaces of the first to fourth chips 14A to 14D. The upper surfaces of the first to fourth chips 14A to 14D and an upper surface of the molding layer 14E provided on and surrounding the first to fourth chips 14A to 14D may be at the same height and may form the same surface. The upper surfaces of the first to fourth chips 14A to 14D and the upper surface of the molding layer 14E surrounding the first to fourth chips 14A to 14D may be covered by a transparent substrate 16 and may be in contact with a lower surface of the transparent substrate 16.

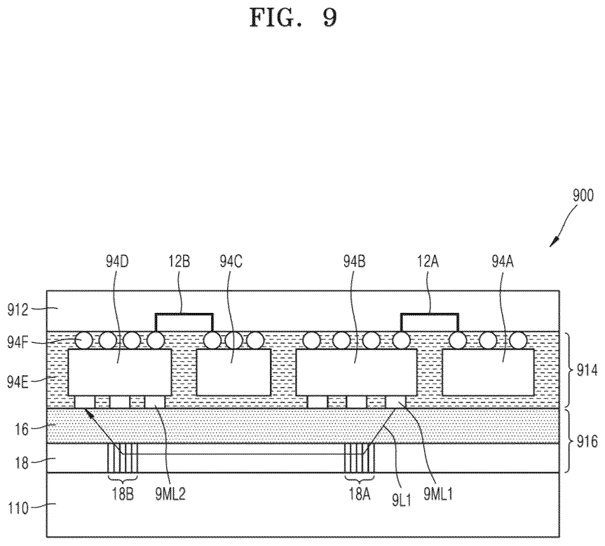

FIG. 9 illustrates a ninth chip package 900 according to one or more embodiments. The ninth chip package 900 may correspond to an inverted version of the first chip package 100.

Referring to FIG. 9, an optical interconnection layer 916, a chiplet layer 914, and an electrical interconnection layer 912 are sequentially stacked on a base substrate 110. The optical interconnection layer 916 includes an optical transmission layer 18 and a transparent substrate 16 that are sequentially stacked. The chiplet layer 914 may include a first chip 94A, a second chip 94B, a third chip 94C, and a fourth chip 94D. The first chip 94A may correspond to an inverted version of the first chip 14A shown in FIG. 1. The second chip 94B may correspond to an inverted version of the second chip 14B shown in FIG. 1. The third chip 94C may correspond to an inverted version of the third chip 14C shown in FIG. 1. The fourth chip 94D may correspond to an inverted version of the fourth chip 14D shown in FIG. 1. A third microlens 9ML1, corresponding to the first microlens ML1 shown in FIG. 1 is provided between the second chip 94B and the optical interconnection layer 916. A fourth microlens 9ML2, corresponding to the second microlens ML2 shown in FIG. 1 is provided between the fourth chip 94D and the optical interconnection layer 916. A molding layer 94E, in which the first to fourth chips 94A to 94D are embedded, may correspond to the molding layer 14E shown in FIG. 1. Connection elements 94F are provided between the electrical interconnection layer 912 and the first to fourth chips 94A to 94D to connect (bond) the electrical interconnection layer 912 to the first to fourth chips 94A to 94D. The connection elements 94F may correspond to the connection elements 14F shown in FIG. 1. Light 9L1 emitted downward from the second chip 94B may pass through a first optical element 18A and a second optical element 18B before being incident on the fourth chip 94D.

At least one of the features of the second to eighth chip packages 200, 300, 400, 500, 600, 700, and 800 described above may also be applied to the ninth chip package 900.

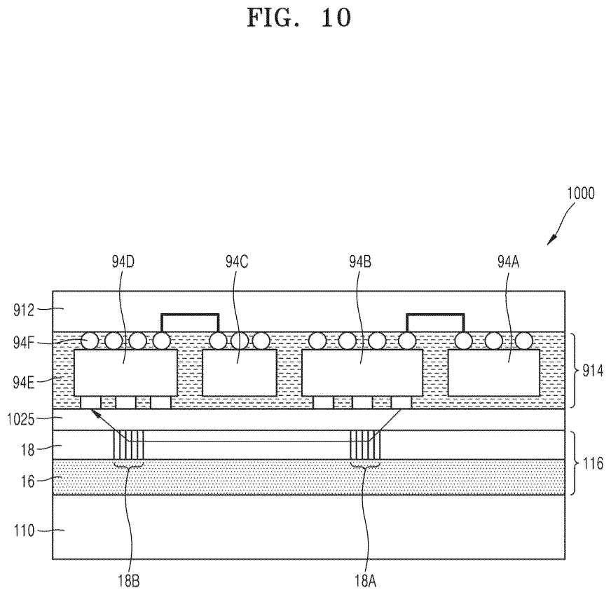

FIG. 10 illustrates a tenth chip package 1000 according to one or more embodiments. The tenth chip package 1000 may correspond to a modification of the ninth chip package 900. Therefore, only parts different from the ninth chip package 900 will now be described.

Referring to FIG. 10, the tenth chip package 1000 may correspond to a modification of the ninth chip package 900, in which the optical interconnection layer 916 is replaced with the optical interconnection layer 116 shown in FIG. 1, and a protective layer 1025 is provided between the optical interconnection layer 116 and the chiplet layer 914. The protective layer 1025 may be a planarization layer, and an upper surface of the protective layer 1025 may be entirely flat. In one example, the protective layer 1025 may include the same material as a material of the first protective layer 76 shown in FIG. 7. In one example, the protective layer 1025 may include silicon oxide (for example, SiO2), but is not limited thereto.

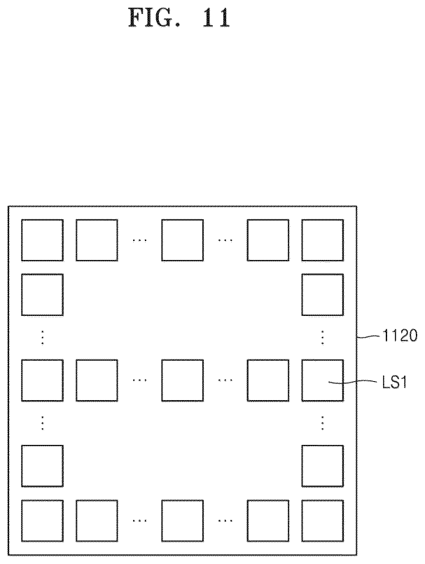

FIG. 11 is a plan view illustrating, as an example, a two-dimensional light source array 1120 that may be included in the second chips 14B and 94B of the first to tenth chip packages 100, 200, 300, 400, 500, 600, 700, 800, 900, and 1000 to emit light.

Referring to FIG. 11, the light source array 1120 includes a plurality of light sources LS1. The light sources LS1 may include VCSELs, but are not limited thereto. The light sources LS1 may be arranged in a grid pattern aligned in horizontal and vertical directions.

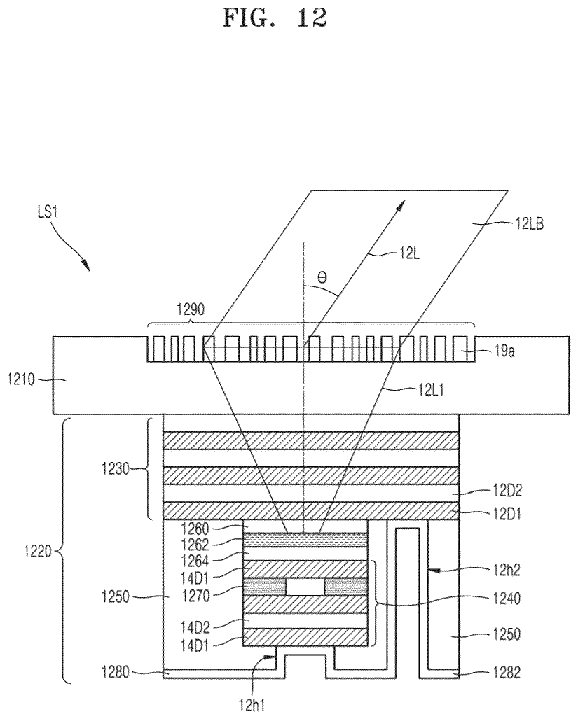

FIG. 12 illustrates an example of the light sources LS1 shown in FIG. 11.

Referring to FIG. 12, the light source LS1 includes a substrate 1210, a VCSEL 1220 provided under the substrate 1210, and a metasurface 1290 formed on the opposite side of the substrate 1210 from the VCSEL 1220.

In one example, the substrate 1210 may include a Group III-V compound semiconductor. In one example, the substrate 1210 may include a GaAs substrate, but is not limited thereto. The VCSEL 1220 includes a first distributed Bragg reflector (DBR) layer 1230 and a second DBR layer 1240 that are sequentially provided under the substrate 1210. The second DBR layer 1240 may be narrower than the first DBR layer 1230.

An active layer 1262, in which light is generated, is provided between the first DBR layer 1230 and the second DBR layer 1240. A first semiconductor layer 1260 is provided between the active layer 1262 and the first DBR layer 1230. A second semiconductor layer 1264 is provided between the active layer 1262 and the second DBR layer 1240. The first semiconductor layer 1260 may be in direct contact with both the active layer 1262 and the first DBR layer 1230, but is not limited thereto. The second semiconductor layer 1264 may be in direct contact with both the active layer 1262 and the second DBR layer 1240. The first and second semiconductor layers 1260 and 1264 may be compound semiconductor layers (for example, Group III-V compound semiconductor layers), but are not limited thereto. One of the first and second semiconductor layers 1260 and 1264 may be a p-type semiconductor layer doped with a p-type dopant, and the other of the first and second semiconductor layers 1260 and 1264 may be an n-type semiconductor layer doped with an n-type dopant. The first DBR layer 1230 may include a layered structure in which a first material layer 12D1 and a second material layer 12D2 having different refractive indices are alternately stacked in a repeated pattern. The second DBR layer 1240 may include a layered structure in which a third material layer 14D1 and a fourth material layer 14D2 having different refractive indices are alternately stacked in a repeated pattern. In one example, the first and third material layers 12D1 and 14D1 may include the same material or different materials. In one example, the second and fourth material layers 12D2 and 14D2 may include the same material or different materials. An aperture 1270 may be provided in one layer of the second DBR layer 1240. The aperture 1270 may be spaced apart from the second semiconductor layer 1264 or adjacent to the second semiconductor layer 1264. Laser light 12L1 generated in a cavity formed by the first and second DBR layers 1230 and 1240 may be output upward sequentially through the first DBR layer 1230, the substrate 1210, and the metasurface 1290. The metasurface 1290 may be formed in a region of the substrate 1210 in which the laser light 12L1 reaches substrate 1210. The metasurface 1290 may include a plurality of meta-patterns 19a. In one example, each of the meta-patterns 19a may include a pattern having a feature (for example, height, width, pitch, or the like) smaller than the wavelength of the laser light 12L1. In one example, each of the meta-patterns 19a may include a nanopillar. The shape and size of each of the meta-patterns 19a may be designed such that the laser light 12L1 passing through the meta-pattern 19a may have a given phase delay value at the position of the metal-pattern 19a. Due to the given phase delay value, the laser light 12L1 may be deflected by a deflection angle θ. Therefore, the laser light 12L1 incident on the metasurface 1290 may be output at an angle due to deflection by the meta-patterns 19a. Reference numeral 12LB refers to a light beam deflected by the metasurface 1290, and reference numeral 12L refers to light representing the light beam 12LB. The light 12L deflected by the metasurface 1290 may be incident on a first optical element 18A of an optical interconnection layer 116. The optical element 18A may be referred to as a first optical coupling element. Considering this operation of the metasurface 1290, the metasurface 1290 may also be referred to as a meta-deflector or meta-lens.

A stacked structure formed by the second DBR layer 1240, the active layer 1262, the first semiconductor layer 1260, and the second semiconductor layer 1264 may be covered by a polymer layer 1250. In addition, a lower surface of the first DBR layer 1230 surrounding the first semiconductor layer 1260 may also be covered by the polymer layer 1250. In one example, the polymer layer 1250 may include an insulating layer. The polymer layer 1250 may include a first hole 12h1 through which a lower surface of the second DBR layer 1240 is exposed, and a second hole 12h2 through which the lower surface of the first DBR layer 1230 is exposed. A lower surface of a lowest layer of the second DBR layer 1240 may be exposed through the first hole 12h1, and a lower surface of a lowest layer of the first DBR layer 1230 may be exposed through the second hole 12h2. A first electrode layer 1280, which is provided on and covers surfaces exposed through the first hole 12h1, and a second electrode layer 1282, which covers surfaces exposed through the second hole 12h2, may be formed on a lower surface of the polymer layer 1250. The first electrode layer 1280 may be in direct contact with the lower surface of the second DBR layer 1240 through the first hole 12h1. The second electrode layer 1282 may be in direct contact with the lower surface of the first DBR layer 1230 through the second hole 12h2. The first and second electrode layers 1280 and 1282 are spaced apart from each other.

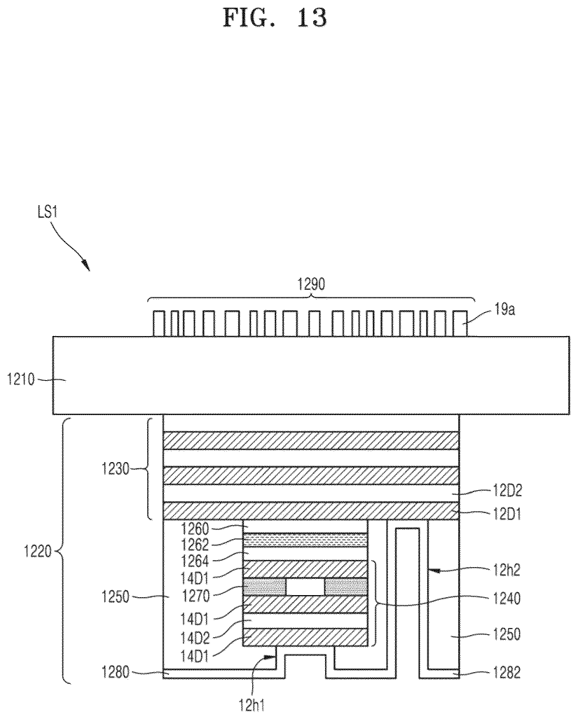

In one example, the metasurface 1290 may be formed in the substrate 210 by etching an upper surface of the substrate 1210. As another example, the metasurface 1290 may be formed at the upper surface of the substrate 1210 as illustrated in FIG. 13. In one example, the metasurface 1290 shown in FIG. 13 may be formed by depositing a material layer including the same material as the meta-patterns 19a on the upper surface of the substrate 1210, and then patterning the material layer using a photolithography process.

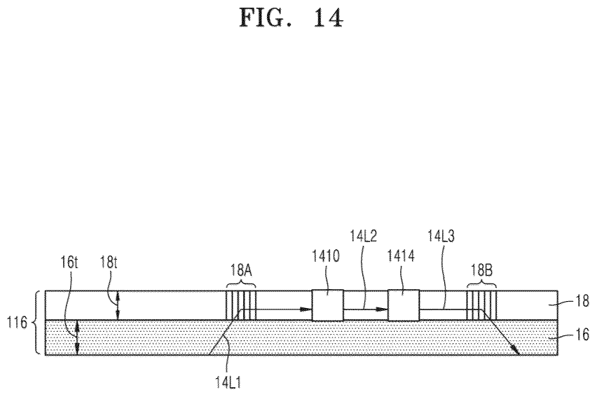

In one example, the optical transmission layer 18 of the optical interconnection layer 116 of each of the first to eighth chip packages 100 to 800 and the tenth chip packages 1000 may include an optical multiplexer (MUX) 1410 and an optical demultiplexer (DEMUX) 1414 between the first optical element 18A and the second optical element 18B as illustrated in FIG. 14. For ease of illustration, FIG. 14 only shows the optical interconnection layer 116. The optical MUX 1410 and the optical DEMUX 1414 may also be provided between the first and second optical elements 18A and 18B of the optical interconnection layer 916 of the ninth chip package 900. In addition to the first optical element 18A, the optical transmission layer 18 may further include a plurality of optical elements performing the same role (operation) as the first optical element 18A. Light deflected by the plurality of optical elements is incident on the optical MUX 1410, multiplexed in the optical MUX 1410, and then transmitted to the optical DEMUX 1414. Light 14L3 split by the optical DEMUX 1414 may reach the fourth chip 14D through the second optical element 18B and may be detected by a light-receiving element (photodetector) included in the fourth chip 14D. In addition to the second optical element 18B, the optical transmission layer 18 may further include a plurality of optical elements performing the same role (operation) as the second optical element 18B. Therefore, the light 14L3 split by the optical DEMUX 1414 may reach the fourth chip 14D through the plurality of optical elements and may be detected by light-receiving elements that are included in the fourth chip 14D and correspond to the plurality of optical elements.

In FIG. 14, reference numeral 14L2 refers to light multiplexed by the optical MUX 1410. Multiplexed light may include a plurality of independent pieces of data.

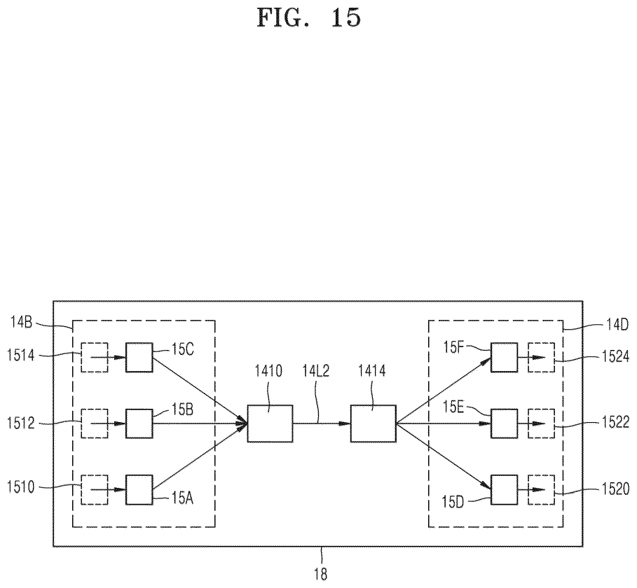

FIG. 15 is a plan view illustrating an example of a planar configuration of the optical transmission layer 18 shown in FIG. 14.

Referring to FIG. 15, the optical transmission layer 18 includes a first light deflection element 15A, a second light deflection element 15B, and a third light deflection element 15C, a fourth light deflection element 15D, a fifth light deflection element 15E, and a sixth light deflection element 15F, and the optical MUX 1410 and the optical DEMUX 1414 arranged between the first to third light deflection elements 15A to 15C and the fourth to sixth light deflection elements 15D to 15F. The first to third light deflection elements 15A to 15C may deflect light incident from the second chip 14B toward the optical MUX 1410. Each of the first to third light deflection elements 15A to 15C may perform the same role (operation) as the first optical element 18A. In one example, the first optical element 18A may be one of the first to third light deflection elements 15A to 15C. The fourth to sixth light deflection elements 15D to 15F may deflect light incident from the optical DEMUX 1414 toward the fourth chip 14D. Each of the fourth to sixth light deflection elements 15D to 15F may perform the same role (operation) as the second optical element 18B. In one example, the second optical element 18B may be one of the fourth to sixth light deflection elements 15D to 15F. The optical MUX 1410 collects and multiplexes light incident from the first to third light deflection elements 15A to 15C, and then transmits multiplexed light 14L2 to the optical DEMUX 1414. The optical DEMUX 1414 demultiplexes the multiplexed light 14L2 and transmit the demultiplexed light to the fourth to sixth light deflection elements 15D to 15F. An optical splitter may be provided between the optical DEMUX 1414 and the fourth to sixth light deflection elements 15D to 15F, and light split by the optical splitter may be incident on the fourth to sixth light deflection elements 15D to 15F. The optical splitter may also be referred to as an optical separator.

Reference numerals 1510, 1512, and 1514 refer to three light sources that correspond to the first to third light deflection elements 15A to 15C among the light sources of the light source array of the second chip 14B. Reference numerals 1520, 1522, and 1524 refer to three light-receiving elements (photodetectors) that correspond to the fourth to sixth light deflection elements 15D to 15F among light-receiving elements of a light-receiving element array of the fourth chip 14D.

For ease of illustration, FIG. 15 illustrates only three elements that deflect light incident from the second chip 14B and only three elements that deflect light incident from the optical DEMUX 1414 toward the fourth chip 14D. However, the number of each type of deflection element may be greater or fewer than three. In addition, for ease of illustration, FIG. 15 illustrates only the second and fourth chips 14B and 14D among the first to fourth chips 14A to 14D provided under the optical transmission layer 18.

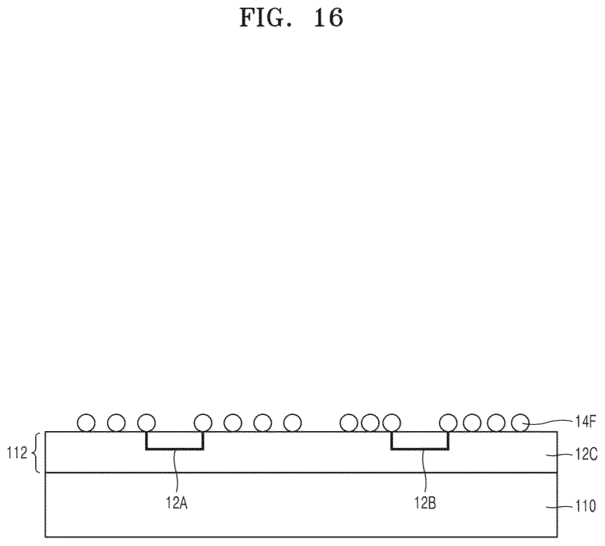

Operations in a method of manufacturing a chip package will now be described according to one or more embodiments with reference to FIGS. 16 to 32.

FIGS. 16 to 21 illustrate operations in a method of manufacturing the first chip package 100, according to one or more embodiments.

Referring to FIG. 16, first, an electrical interconnection layer 112 is formed on a base substrate 110. The electrical interconnection layer 112 may include wires 12A and 12B for electrically connecting chips to be mounted. The configuration and arrangement of the wires 12A and 12B may be designed considering the operational characteristics of chips to be mounted. Connection elements 14F may be formed on the electrical interconnection layer 112. The connection elements 14F may be in contact with exposed portions of the wires 12A and 12B.

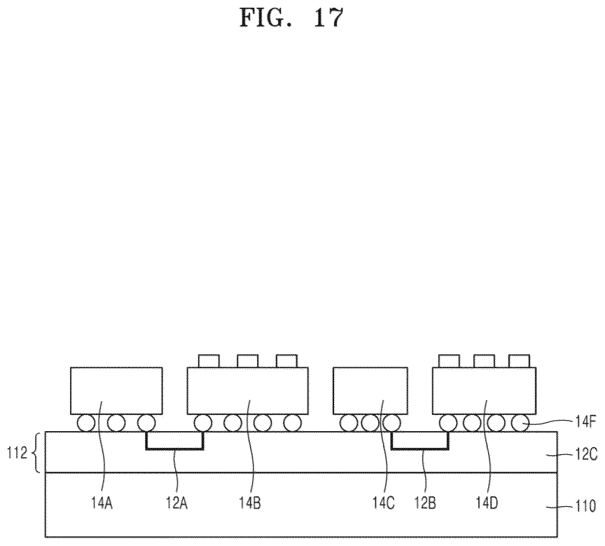

Next, referring to FIG. 17, the first to fourth chips 14A to 14D are mounted on the electrical interconnection layer 112. Each of the first to fourth chip 14A to 14D may be mounted such that terminals of the chip may be in contact with connection elements 14F formed in a mounting area of the chip. During the mounting, the first to fourth chips 14A to 14D and the electrical interconnection layer 112 may be electrically coupled (bonded) to each other through the connection elements 14F.

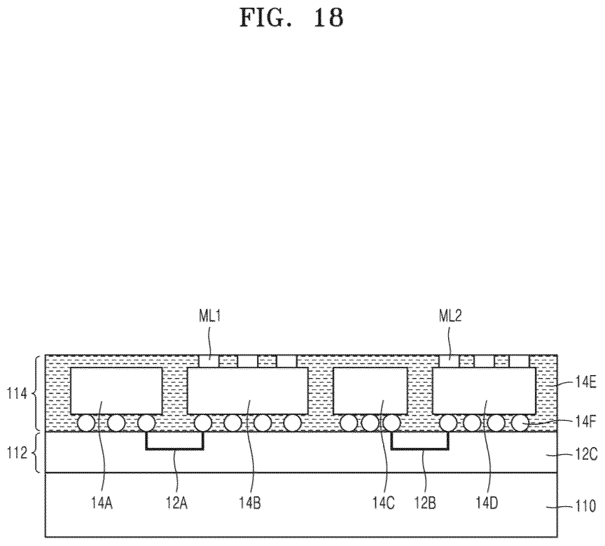

Next, referring to FIG. 18, the first to fourth chips 14A to 14D are embedded in a molding layer 14E. In one example, space between the first to fourth chips 14A to 14D may be filled with the molding layer 14E, and a between the electrical interconnection layer 112 and the first to fourth chips 14A to 14D may also be filled with the molding layer 14E. In addition, lateral and upper surfaces of the first to fourth chips 14A to 14D may be covered with the molding layer 14E. After forming the molding layer 14E, an upper surface of the molding layer 14E may be planarized. The planarizing may be performed until microlenses ML1 and ML2 of the second and fourth chips 14B and 14D are exposed.

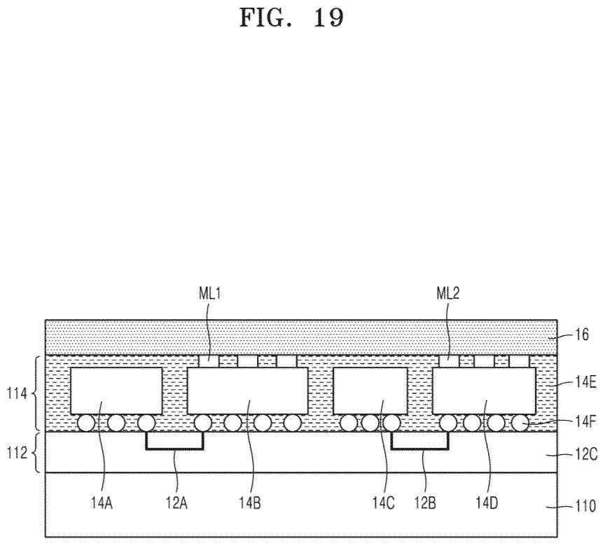

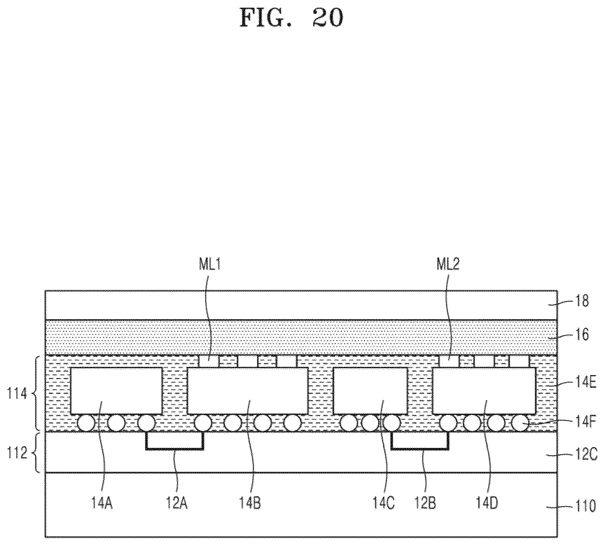

Next, referring to FIG. 19, a transparent substrate 16 is formed on the molding layer 14E. Then, as shown in FIG. 20, an optical transmission layer 18 operating as a waveguide is formed on the transparent substrate 16.

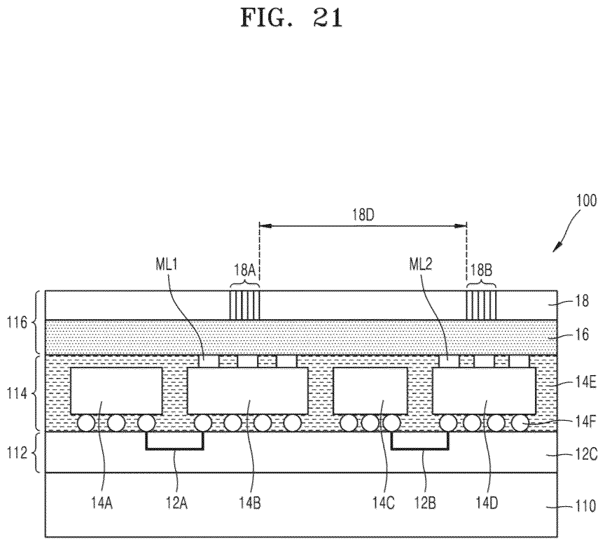

Next, referring to FIG. 21, portions of the optical transmission layer 18 are etched to form a first optical element 18A at a position corresponding to the second chip 14B and a second optical element 18B at a position corresponding to the fourth chip 14D. The first and second optical elements 18A and 18B may be formed in the shape of diffraction gratings, or may be formed as metasurfaces including meta-patterns by using meta-technology. Because the first and second optical elements 18A and 18B are elements that change the propagation direction of incident light, patterns of the first and second optical elements 18A and 18B may be configured considering both the incident and outgoing directions of light. In this manner, the first chip package 100 may be formed.

After forming the first and second optical elements 18A and 18B, light reflection mirrors 204 and 204′ may be formed at the positions illustrated in FIG. 2, or a protective layer 315 may be formed on the optical transmission layer 18 to cover the first and second optical elements 18A and 18B as shown in FIG. 3.

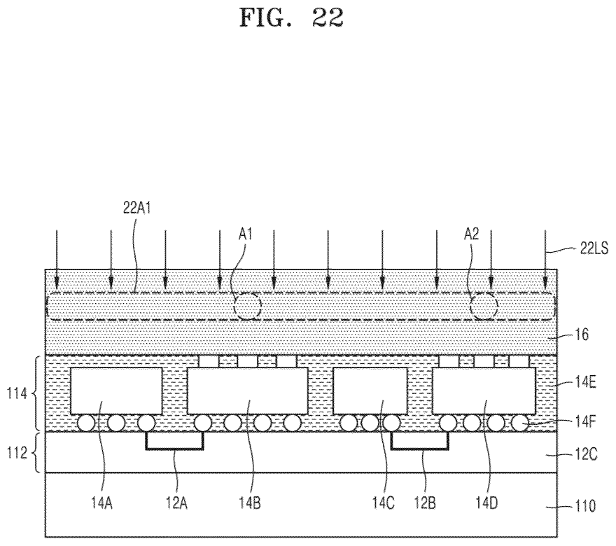

FIGS. 22 to 24 illustrate, as an example, a method of manufacturing the fourth chip package 400.

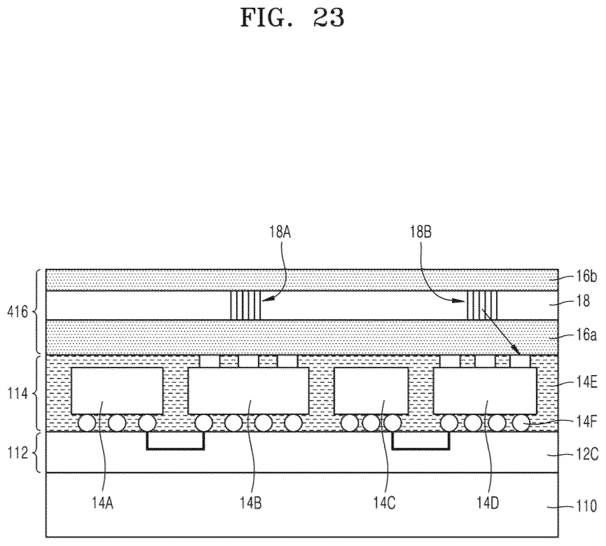

Referring to FIG. 22, the method of manufacturing the fourth chip package 400 may follow the method of manufacturing the first chip package 100 up to the formation of a transparent substrate 16. After forming the transparent substrate 16, a region 22A1 in which an optical transmission layer 18 is to be formed is defined within the transparent substrate 16, and then, laser light 22LS is projected onto the defined region 22A1 to modify the refractive index of the defined region 22A1. The refractive index of the defined region 22A1 may become higher than the refractive index of the remaining region of the transparent substrate 16 due to the projection of the laser light 22LS. In this manner, the defined region 22A1 within the transparent substrate 16 may be used as an optical transmission layer 18 as shown in FIG. 23. A first region A1 and a second region A2 in the defined region 22A1 are regions in which first and second optical elements 18A and 18B are to be formed. Therefore, during the projection of the laser light 22LS, the laser light 22LS may be directed onto the first and second regions A1 and A2 in such a manner that patterns corresponding to the patterns included in the first and second optical elements 18A and 18B may be drawn in the first and second regions A1 and A2. In this manner, as shown in FIG. 23, the optical transmission layer 18 and the first and second optical elements 18A and 18B may be formed within the transparent substrate 16. Thereafter, as illustrated in FIG. 2, light reflection mirrors 204 and 204′ may be formed on an upper surface of the transparent substrate 16.

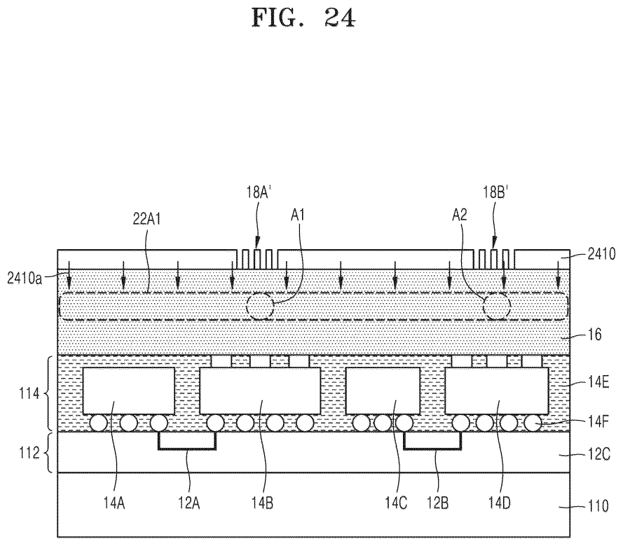

FIG. 24 illustrates another method of forming the optical transmission layer 18 embedded in the transparent substrate 16, as another method of manufacturing the fourth chip package 400.

Referring to FIG. 24, a metal layer 2410, which operates as a source of metal ions, is formed on the transparent substrate 16. The metal layer 2410 may entirely correspond to the region 22A1 defined within the transparent substrate 16 as a region in which the optical transmission layer 18 is to be formed. The first and second regions A1 and A2 in the defined region 22A1 are regions in which the first and second optical elements 18A and 18B are to be formed. Therefore, during the formation of the metal layer 2410, metal patterns 18A′ and 18B′ corresponding to the patterns of the first and second optical elements 18A and 18B may be formed in portions of the metal layer 2410 that correspond to the first and second regions A1 and A2.

As the metal layer 2410 is formed, metal ions 2410a may diffuse from the metal layer 2410 into the defined region 22A1 of the transparent substrate 16, enabling substitution. As a result, the refractive indices of the defined region 22A1 and the first and second regions A1 and A2 may be greater than the refractive index of the remaining region of the transparent substrate 16. Thus, as shown in FIG. 23, the defined region 22A1, the first region A1, and the second region A2 may operation as the optical transmission layer 18, the first optical element 18A, and the second optical element 18B, respectively.

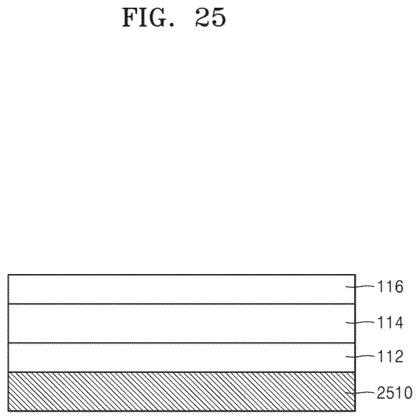

FIGS. 25 to 28 illustrate operations in a method of manufacturing the ninth chip package 900. For ease of illustration, in FIG. 25 and later drawings, each layer of a chip package is simply shown as a tetragonal box, and the internal structure of each layer is omitted.

Referring to FIG. 25, first, an electrical interconnection layer 112, a chiplet layer 114, and an optical interconnection layer 116 are sequentially formed on a separation substrate 2510.

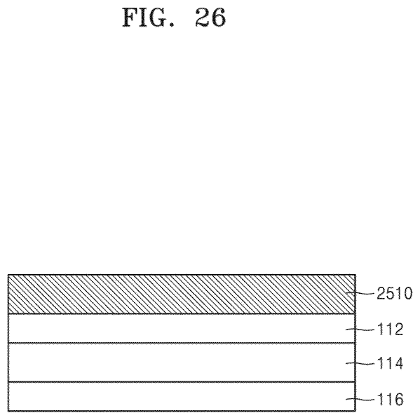

Next, referring to FIG. 26, the separation substrate 2510 is flipped upside down, positioning the separation substrate 2510 uppermost and the optical interconnection layer 116 lowermost.

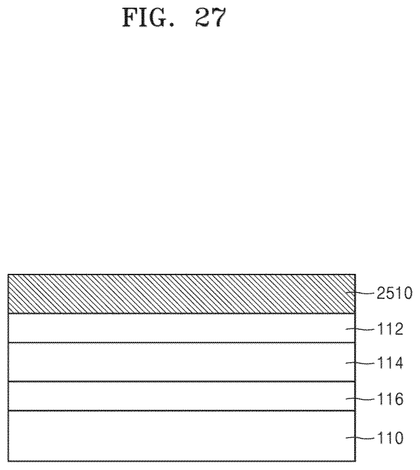

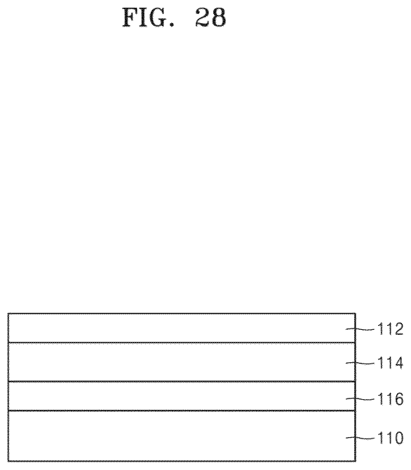

Next, referring to FIG. 27, the flipped separation substrate 2510 is placed above a base substrate 110 such that the optical interconnection layer 116 may face the base substrate 110. In this state, the separation substrate 2510 is lowered to bond the optical interconnection layer 116 and the base substrate 110 to each other. For the bonding, a bonding layer or an adhesive layer may be provided on the base substrate 110 or the optical interconnection layer 116. After the optical interconnection layer 116 and the base substrate 110 are bonded to each other, the separation substrate 2510 is removed. To this end, a separation layer, which allows detachment upon irradiation (emission) with energy (for example, ultraviolet rays), may be provided between the separation substrate 2510 and the electrical interconnection layer 112. However, one or more embodiments are not limited thereto. FIG. 28 illustrates a result after the separation substrate 2510 is removed.

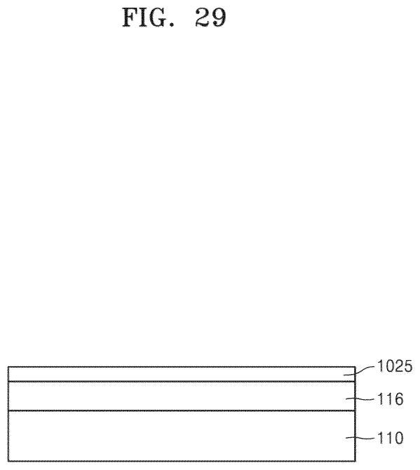

FIGS. 29 to 32 illustrate operations in a method of manufacturing the tenth chip package 1000.

Referring to FIG. 29, an optical interconnection layer 116 is formed on a base substrate 110, and then, a protective layer 1025 serving as a planarization layer is formed on the optical interconnection layer 116.

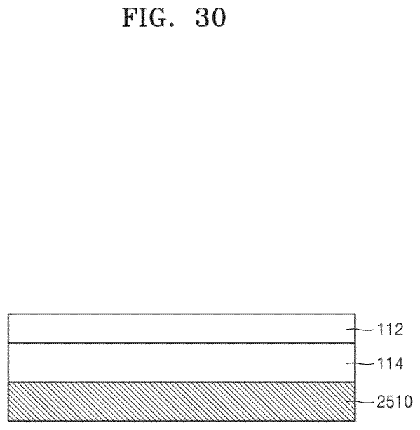

Next, referring to FIG. 30, an electrical interconnection layer 112 and a chiplet layer 114 are sequentially formed on a separation substrate 2510.

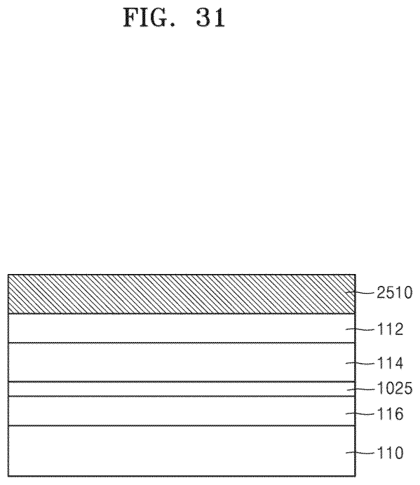

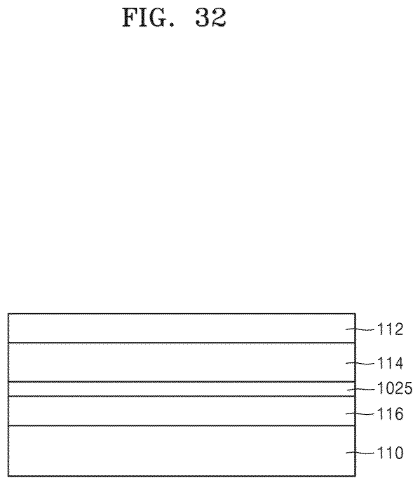

Next, referring to FIG. 31, the separation substrate 2510 is flipped, and the chiplet layer 114 is bonded to the protective layer 1025. To this end, a bonding layer or an adhesive layer may be formed between the chiplet layer 114 and the protective layer 1025. Thereafter, the separation substrate 2510 is removed. FIG. 32 illustrates a result after the separation substrate 2510 is removed.

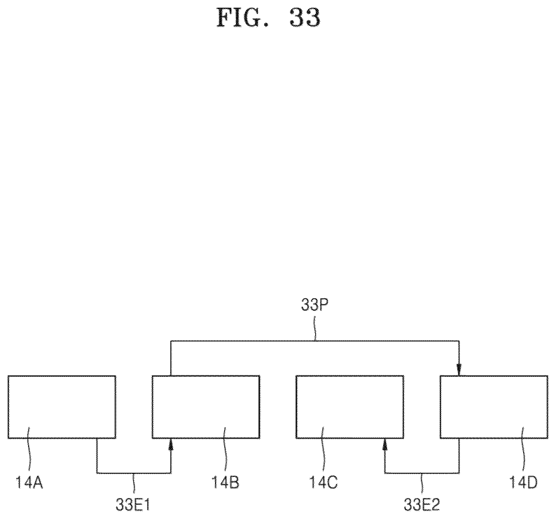

FIG. 33 illustrates data transmission and reception in a chip package according to one or more embodiments. Data may be delivered or transmitted in the form of electrical signals or optical signals.

Referring to FIG. 33, a first electrical signal 33E1 generated in a first chip 14A may be transmitted to a second chip 14B through a path below the first chip 14A and the second chip 14B. The first electrical signal 33E1 may include data processed by the first chip 14A or stored in the first chip 14A. The first electrical signal 33E1 may operate as a driving signal for a light source included in the second chip 14B, and light output from a light source of the second chip 14B may be modulated in response to the driving signal. For example, the first electrical signal 33E1 transmitted from the first chip 14A is converted into an optical signal 33P by the second chip 14B and is then output. The optical signal 33P output from the second chip 14B is transmitted to a fourth chip 14D through a path above the second chip 14B, a third chip 14C, and the fourth chip 14D. Light transmitted to the fourth chip 14D is detected by a photodetector (for example, a PD) included in the fourth chip 14D and is optoelectronically converted. As a result, the fourth chip 14D generates a second electrical signal (for example, photocurrent) 33E2, and the second electrical signal 33E2 may be transmitted to the third chip 13D through a path below the fourth chip 14D and the third chip 14C. In the third chip 14C, the second electrical signal 33E2 may be converted into a voltage signal by an amplifier circuit (for example, a transimpedance amplifier (TIA)). Then, the voltage signal may be restored to an original signal through a subsequent signal processing circuit.

The one or more embodiments described above may suggest various embodiments as follows.

According to one or more embodiments, a chip package may include a chiplet layer including a plurality of chips, an electrical interconnection layer provided on a first side of the chiplet layer and including a path through which electrical signals generated from the chiplet layer are transmitted, and an optical interconnection layer provided on a second side of the chiplet layer and including a path through which optical signals generated from the chiplet layer are transmitted. The electrical interconnection layer and the optical interconnection layer are opposite each other with the chiplet layer therebetween.

According to one or more embodiments of the chip package, the electrical interconnection layer may be provided below the chiplet layer, and the optical interconnection layer may be provided above the chiplet layer.

According to one or more embodiments of the chip package, the electrical interconnection layer may be provided above the chiplet layer, and the optical interconnection layer may be provided below the chiplet layer.

In this case, the optical interconnection layer may include a first transparent layer, and a first optical transmission layer provided on the first transparent layer and operating as a waveguide.

In this case, the chip package may further include a second transparent layer on the first optical transmission layer, and a second optical transmission layer on the second transparent layer.

In this case, the optical interconnection layer may include an optical transmission layer serving as a waveguide, and a transparent layer provided on the optical transmission layer.

When the electrical interconnection layer is provided below the chiplet layer and the optical interconnection layer is provided above the chiplet layer, the optical interconnection layer may include a first transparent layer, and a first optical transmission layer provided on the first transparent layer and serving as a waveguide.

In this case, the optical interconnection layer may further include a second transparent layer provided on the first optical transmission layer, and a second optical transmission layer provided on the second transparent layer.

In this case, the chip package may further include a mirror provided on the first optical transmission layer.

In this case, the first optical transmission layer may include a plurality of optical elements, and the chip package further may include a protective layer provided on the first optical transmission layer to be provided on and cover the plurality of optical elements.

In this case, the plurality of chips may include a chip (light-emitting chip) including a light source, and a chip (light-receiving chip) including a photodetector element. The first optical transmission layer may include a first optical element configured to change a propagation direction of light incident from the light-emitting chip, and a second optical element configured to change a propagation direction of light incident through the first optical element to direct the light onto the light-receiving chip.

In this case, a microlens may be provided between the light-receiving chip and the second optical element.

In this case, a mirror may be provided on the first optical element.

According to one or more embodiments of the chip package, the first optical transmission layer may further include an optical multiplexer and an optical demultiplexer that are provided between the first optical element and the second optical element.

According to one or more embodiments of the chip package, the first and second optical elements may include a grating coupler.

According to one or more embodiments of the chip package, the light source may include a vertical-cavity surface-emitting laser (VCSEL), and the VCSEL may include a metasurface at a light-emitting surface thereof to deflect emitted light toward the first optical element.

In this case, the metasurface may be engraved in the light-emitting surface.

In this case, the metasurface may be formed on the light-emitting surface.

In this case, a microlens may be provided on the metasurface.

According to one or more embodiments of the chip package, the plurality of chips may be mounted on the electrical interconnection layer, and the chiplet layer may further include a molding layer filling space between the plurality of chips and enclosing the plurality of chips.

In this case, two of the plurality of chips may be stacked in the vertical direction.

In this case, the chip package may further include a chip mounted on the electrical interconnection layer and not embedded in the molding layer, and the chip that is not embedded in the molding layer may include a chip stack in which a plurality of chips are stacked in the vertical direction. The chip stack may include high bandwidth memory (HBM).

According to one or more embodiments, a method of manufacturing a chip package includes forming an electrical interconnection layer on a base substrate, forming a chiplet layer including a plurality of chips, on the electrical interconnection layer, and forming an optical interconnection layer on the chiplet layer.

According to one or more embodiments of the method of manufacturing a chip package, the forming of the chiplet layer may include forming connection elements apart from each other on the electrical interconnection layer, mounting the plurality of chips such that the plurality of chips may be in contact with the connection elements, and forming a molding layer and planarizing a surface of the molding layer, the molding layer filling space between the plurality of chips and enclosing the plurality of chips.

According to one or more embodiments of the method of manufacturing a chip package, the forming of the optical interconnection layer may include forming a first transparent layer on the chiplet layer, and forming a first optical transmission layer on the first transparent layer.

According to one or more embodiments of the method of manufacturing a chip package, the forming of the optical interconnection layer may include forming a first transparent layer on the chiplet layer, and forming an optical transmission layer within the first transparent layer.

According to one or more embodiments of the method of manufacturing a chip package, the forming of the optical transmission layer within the first transparent layer may include increasing the refractive index of a region of the first transparent layer in which the optical transmission layer is to be formed.

According to one or more embodiments, the method of manufacturing a chip package may further include projecting laser light onto a region of the first transparent layer in which the optical transmission layer is to be formed.

According to one or more embodiments, the method of manufacturing a chip package may further include diffusing metal ions in a region of the first transparent layer in which the optical transmission layer is to be formed.

According to one or more embodiments, the method of forming a chip package may further include forming a second transparent layer on the first optical transmission layer, and forming a second optical transmission layer on the second transparent layer.

According to one or more embodiments, there is provided a method of transmitting and receiving data in a chip package, the method including transmitting a first electrical signal generated in a first chip to a second chip adjacent to the first chip, and outputting an optical signal corresponding to the first electrical signal from the second chip and transmitting the optical signal to a third chip. The first electrical signal may be transmitted below the first and second chips, and the optical signal may be transmitted above the second and third chips.

According to one or more embodiments, the method of transmitting and receiving data in a chip package may further include transmitting, to a fourth chip, current generated when the third chip optoelectronically converts the optical signal. The current is transmitted below the third and fourth chips.

As described above, in the chip package including interconnection layers according to one or more of the one or more embodiments described above, electrical signals are transmitted and received below the chiplet layer through the electrical interconnection layer, and optical signals are transmitted and received above the chiplet layer through the optical interconnection layer. In this manner, a path for transmitting and receiving electrical signals is completely separated from a path for transmitting receiving optical signals. In addition, the path for transmitting and receiving electrical signals is formed between adjacent chips, and the path for transmitting and receiving optical signals is formed between relatively distant chips. As a result, wiring for transmitting and receiving electrical signals may be shortened to prevent parasitic effects that may occur when the wiring is relatively long, and optical transmission efficiency may be improved. Therefore, data transmission and reception time may be reduced. Furthermore, the chip package or a computing system including the chip package may have a high operating speed and low power consumption and may be manufactured through simple processes.

Moreover, because the electrical interconnection layer and the optical interconnection layer are completely separated from each other in the chip package, monitoring such as monitoring for inspection may be more easily performed on the optical interconnection layer.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A chip package comprising:
a chiplet layer comprising a plurality of chips;
an electrical interconnection layer on a first side of the chiplet layer, the electrical interconnection layer comprising a path configured to transmit electrical signals generated from the chiplet layer; and
an optical interconnection layer on a second side of the chiplet layer opposite to the electrical interconnection layer, the optical interconnection layer comprising a path configured to transmit optical signals generated from the chiplet layer.

2. The chip package of claim 1, the optical interconnection layer is between the chiplet layer and a base substrate.

3. The chip package of claim 1, wherein the electrical interconnection layer is between the chiplet layer and a base substrate.

4. The chip package of claim 2, wherein the optical interconnection layer comprises:
a first transparent layer; and
a first optical transmission layer on the first transparent layer, the first optical transmission layer being configured to operate as a waveguide;

5. The chip package of claim 4, further comprising:
a second transparent layer on the first optical transmission layer; and
a second optical transmission layer on the second transparent layer.

6. The chip package of claim 4, further comprising a mirror on the first optical transmission layer.

7. The chip package of claim 4, wherein the first optical transmission layer comprises a plurality of optical elements, and
wherein the chip package further comprises a protective layer on the first optical transmission layer and the plurality of optical elements.

8. The chip package of claim 4, wherein the plurality of chips comprise:
a light-emitting chip comprising a light source; and
a light-receiving chip comprising a photodetector element,
wherein the first optical transmission layer comprises:
a first optical element configured to change a propagation direction of light incident from the light-emitting chip; and
a second optical element configured to change a propagation direction of light incident through the first optical element to direct the light onto the light-receiving chip.

9. The chip package of claim 8, wherein the first optical transmission layer further comprises an optical multiplexer and an optical demultiplexer that are between the first optical element and the second optical element.

10. The chip package of claim 8, wherein the first optical element and the second optical element comprise a grating coupler.

11. The chip package of claim 8, wherein the light source comprises a vertical-cavity surface-emitting laser (VCSEL), and
wherein the VCSEL comprises a metasurface at a light-emitting surface of the VCSEL, the metasurface being configured to deflect emitted light toward the first optical element.

12. The chip package of claim 1, wherein the plurality of chips are on the electrical interconnection layer, and
wherein the chiplet layer further comprises a molding layer filling space between the plurality of chips and enclosing the plurality of chips.

13. The chip package of claim 12, further comprising a chip on the electrical interconnection layer and exposing the molding layer.

14. The chip package of claim 13, wherein the chip exposed by the molding layer comprises a chip stack comprising a plurality of chips stacked in a vertical direction.

15. The chip package of claim 14, wherein the chip stack comprises high bandwidth memory (HBM).

16. A method of manufacturing a chip package, the method comprising:
forming an electrical interconnection layer on a base substrate;
forming a chiplet layer on the electrical interconnection layer, the chiplet layer comprising a plurality of chips; and
forming an optical interconnection layer on the chiplet layer opposite to the electrical interconnection layer.

17. The method of claim 16, wherein the forming of the chiplet layer comprises:
forming connection elements spaced apart from each other on the electrical interconnection layer;
forming the plurality of chips to contact the connection elements; and
forming a molding layer and planarizing a surface of the molding layer, the molding layer filling space between the plurality of chips and enclosing the plurality of chips.

18. The method of claim 16, wherein the forming of the optical interconnection layer comprises:
forming a first transparent layer on the chiplet layer; and
forming a first optical transmission layer on the first transparent layer.

19. The method of claim 18, further comprising:
forming a second transparent layer on the first optical transmission layer; and
forming a second optical transmission layer on the second transparent layer.

20. A method of transmitting and receiving data in a chip package, the method comprising:
transmitting a first electrical signal generated from a first chip to a second chip adjacent to the first chip; and
outputting an optical signal corresponding to the first electrical signal from the second chip and transmitting the optical signal to a third chip,
wherein the first electrical signal is transmitted on a first side of the first chip and a first side of the second chip, and the optical signal is transmitted on a second side of the second chip and a second side of the third chip opposite to the first side.
